(19) United States
(12) Patent Application Publication
(10) Pub. No.: US 2024/0154387 A1
(43) Pub. Date: May 9, 2024

(54) EMISSION WAVELENGTH TUNING OF VERTICAL-CAVITY SEMICONDUCTOR OPTICAL DEVICES BY PROTON IMPLANTATION-INDUCED INTERDIFFUSION

(71) Applicant: NTT RESEARCH, INC., Sunnyvale, CA (US)

(72) Inventors: Michael D. Fraser, Saitama (JP); H. Hoe Tan, Canberra (AU)

(73) Assignees: NTT RESEARCH, INC., Sunnyvale, CA (US); RIKEN, Saitama (JP); The Australian National University, Canberra (AU)

(21) Appl. No.: 18/501,552

(22) Filed: Nov. 3, 2023

Related U.S. Application Data
(60) Provisional application No. 63/422,314, filed on Nov. 3, 2022.

(51) Int. Cl. H01S 5/10; H01S 5/04; H01S 5/34; H01S 5/42

(52) U.S. Cl. CPC H01S 5/1042; H01S 5/041; H01S 5/34; H01S 5/423

(57) ABSTRACT

A microcavity may include a top layer having a tuned photon energy, a bottom layer, and a quantum well layer in between the top layer and the bottom layer and having a tuned exciton energy independent of the tuned photon energy.

### CROSS REFERENCE TO RELATED APPLICATIONS

This application claims priority to U.S. Provisional Application No. 63/422,314, filed Nov. 3, 2022, which is hereby incorporated by reference in its entirety.

### FIELD

This disclosure relates to wavelength tuning of a vertical cavity semiconductor device for one or more of a lasing based emission or a polariton based emission by using proton implantation.

### BACKGROUND

A vertical cavity semiconductor can be used for generating a lasing based emission or a polariton based emission. For the lasing based emission, the vertical cavity semiconductor is biased to create a population inversion with more particles in an upper energy state. These upper energy state particles then drop to the ground state, e.g., electrons combine with holes to release photons. The released photons can bounce off from the mirror surfaces of the semiconductors to stimulate productions of other photons of the same wavelength. Multiple photons are generated and the distances between the mirror surfaces causes the semiconductor to behave as a resonator to generate a coherent radiation of these photons by being frequency/wavelength selective based on the choice of material and structure. On the other hand, to generate the polariton based emission, polaritonics techniques are used. Polaritonics combine features of photonics and electronics, where the signals (e.g., within a resonating cavity) are carried by a mixture of photons and excitons, as opposed to being carried by pure electromagnetic radiation (such as in lasing described above) or an electric current.

### SUMMARY

In some embodiments, a microcavity is disclosed herein. The microcavity may include a top layer having a tuned photon energy, a bottom layer, and a quantum well layer in between the top layer and the bottom layer and having a tuned exciton energy independent of the tuned photon energy.

In some embodiments, an optical chip is disclosed herein. The optical chip may include a plurality of microcavities. Each microcavity may be configured for a corresponding resonant frequency. Each microcavity may include a top layer having a tuned photon energy, a bottom layer, and a quantum well layer in between the top layer and the bottom layer. The quantum well layer may have a tuned exciton energy independent of the tuned photon energy. The corresponding resonant frequency of the microcavity may be based on at least one of the tuned photon energy or the tuned exciton energy.

In some embodiments, a method of generating a coherent radiation may be provided. The method may include exciting a microcavity using a source radiation. The microcavity may include a top layer having a tuned photon energy, a bottom layer, and a quantum well layer in between the top layer and the bottom layer and having a tuned exciton energy independent of the tuned photon energy. The method may further include generating, by the microcavity, a coherent radiation based on at least one of the tuned photon energy or the tuned exciton energy.

### BRIEF DESCRIPTION OF DRAWINGS

FIG. 1 shows an example of a structural diagram and a functional diagram of a cavity illustrating polaritonic principles.

FIG. 2 shows a semiconductor microcavity configured to generate exciton-polaritons, according to example embodiments of this disclosure.

FIG. 3 shows an example implantation of an ion on a microcavity, according to example embodiments of this disclosure.

FIG. 4 shows an example Monte-Carlo ion scattering numerical simulations of ions and vacancy density distributions after an ion implantation, according to example embodiments of this disclosure.

FIG. 5 shows a graph illustrating vacancies distribution in the top DBR of the microcavity, according to example embodiments of this disclosure.

FIG. 6 shows an example graph illustrating experimental photoluminescence (PL) measurements, according to example embodiments of this disclosure.

FIG. 7 shows example charts illustrating softening of the atomically abrupt profile of quantum wells, according to example embodiments of this disclosure.

FIG. 8 shows an example chart illustrating an experimental PL measurement, according to example embodiments of this disclosure.

FIG. 9 shows accumulated results of proton implants at a range of doses at the example implant energies, according to example embodiments of this disclosure.

FIG. 10 shows example charts illustrating polariton condensation and photon lasing transitions, according to example embodiments of this disclosure.

FIG. 11A shows an example method of fabricating of a structured landscape, according to example embodiments of this disclosure.

FIG. 11B shows the different structures generated by the steps of the method shown in FIG. 11A, according to example embodiments of this disclosure.

FIG. 12 shows examples of microcavity shapes and sizes, according to example embodiments of this disclosure.

FIG. 13 shows an example photonic circuit according to example embodiments of this disclosure.

FIG. 14 is a flowchart of an example method for generating a coherent radiation, according to example embodiments of this disclosure.

The figures are for purposes of illustrating example embodiments, but it is understood that the present disclosure is not limited to the arrangements and instrumentality shown in the drawings. In the figures, identical reference numbers identify at least generally similar elements.

### DESCRIPTION

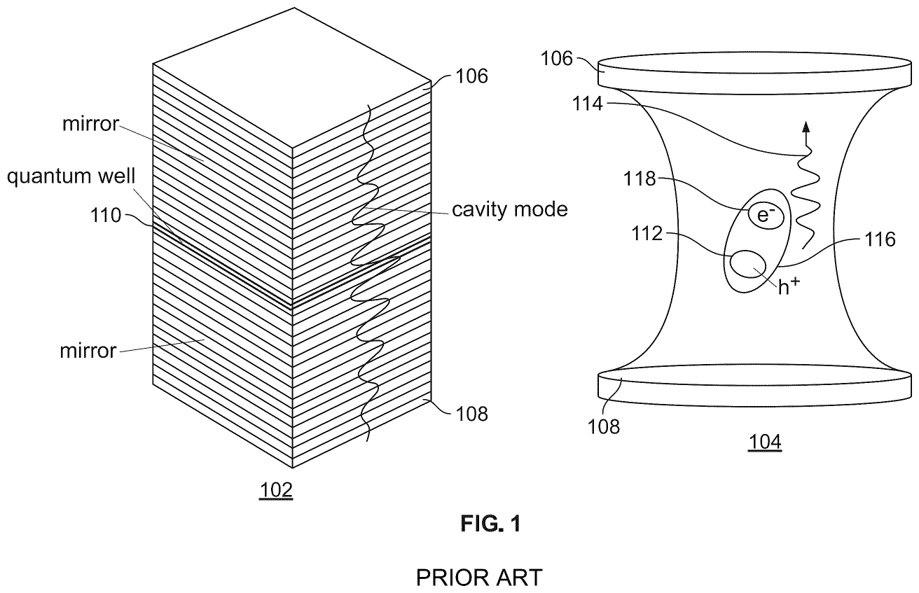

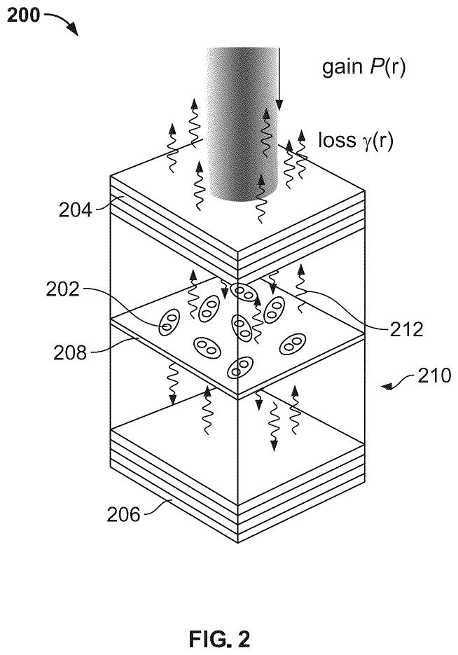

FIG. 1 shows an example of a structural diagram 102 and a functional diagram 104 of a cavity 100 illustrating polaritonic principles. As shown, the cavity 100 includes two mirrors, a first mirror 106 and a second mirror 108, each of which are generally formed by alternating pairs of differently composed Aluminum Gallium Arsenide (AlGaAs) structured as a distributed Bragg reflector (DBR). These mirrors 106, 108 provide reflective surfaces for the photons to bounce within the cavity 100. One or several quantum wells 110 (e.g., a layer with trapped electrons), generally formed by Gallium Arsenide (GaAs) or Indium Gallium Arsenide (InGaAs) and with AlGaAs barriers, are provided at the middle of cavity 100. A photon, either pumped to the cavity 100 or being reflected from one of the mirrors 106, 108, knocks off an electron 118 from its atom (e.g., from the valence band) thereby creating a hole 112. The electron 118 and the hole 112 are oppositely charged and therefore attract each other. The attraction causes them to orbit around each other forming a new hydrogen-like particle called exciton 116. The exciton 116 decays when the electron 118 eventually recombines with the hole 112, causing the exciton 116 to release a photon 114. Therefore, the initial photonic energy is used to generate the exciton 116 is released back to the cavity 100 as another photon 114. The photon 114 resonating frequency may be tuned by changing the distances between and the structure of the mirrors 106, 108. The exciton 116 resonating frequency may be tuned by changes to the thickness and composition of the quantum wells 110.

When the cavity 100 is tuned such that the photon and exciton frequencies are near resonant, a photon at the resonating frequency generates the exciton 116, which in turn decays to generate the photon 114 at the resonating frequency. The photon 114 bounces and generates another exciton, which in turn generates another photon at the resonating frequency. As this exciton-photon energy exchange takes place constantly and rapidly within the cavity 100, a new quasi-particle—an exciton-polariton—is formed having the properties of both photons and excitons. For example, the exciton 116 and the photon 114 may form an exciton-polariton.

A Bose-Einstein Condensate (BEC) of exciton-polaritons (hereafter referred to as a polariton condensate)—quasi-particles composed of excitons (e.g., exciton 116) and photons (e.g., photon 114), as described above—typically form a non-equilibrium condensate featuring finite exciton-polariton lifetimes. The condensate may usually exist in a steady-state of continuous pumping gain and photon loss. To leverage the condensate to produce functional devices, a spatial confinement of the condensate is required. For example, the dynamics and energy of the spatially confined condensate may be controlled—or tuned—to realize the functional devices.

Embodiments disclosed improve upon conventional approaches by tuning vertical cavity semiconductors using proton implantation to independently shift the energies of both exciton and photon components of a quantum well microcavity. Such independent shifting allows tuning of both exciton-polariton states for polariton based emission and photons for a lasing based emission. For example, a post-growth proton implantation and annealing steps may be implemented to create a relatively small local interdiffusion across either the quantum well-barrier material interfaces, or between the layers of the cavity DBR mirrors to induce energy shifts to the exciton or photon components, respectively.

Using one or more techniques discussed herein, semiconductor microcavities can be grown (i.e., fabricated) at a given wavelength, and post processed by the proton implantation to any desired wavelength. The wavelength can be tuned by either the microcavity energy (by tuning photon energy) or the quantum well energy (by tuning exciton energy). Therefore, the tuned single coherent radiation may be either a Bose-Einstein condensate of exciton-polaritons (e.g., generally at low temperatures such as 100 K or below) or may be through photon lasing (generally at room temperature).

FIG. 2 shows a semiconductor microcavity 200 configured to generate exciton-polaritons, according to example embodiments of this disclosure. The semiconductor microcavity 200 may include a top DBR 204 and a bottom DBR 204 defining a photonic microcavity 210 (e.g., a Fabry-Perot type microcavity) within which a number of quantum wells 208 may be embedded. The quantum wells 208 may host excitons 202 that are positioned at the cavity mode anti-nodes (i.e., locations of constructive interferences of incoming and reflected waves). Additionally, the photonic microcavity 210 may host photons 212. Cavity photon and exciton modes, when strongly coupled near resonance, may hybridize to form upper polariton (UP) and lower polariton (LP) modes. The relative energy of the cavity photon mode E_{P} and exciton mode E_{X} may determine the properties of the polariton modes e.g., energies, effective mass, lifetime, and/or interaction strength. Below a critical temperature, by populating the LP mode above a critical density with an optical or electrical pump, a polariton Bose-Einstein condensate is formed. The common materials used for constructing the semiconductor microcavity 200 may be stoichiometric, including compositions of varied alloys of AlGaAs (for the DBRs 204, 206) and (In)GaAs/AlGaAs heterostructures (for the quantum wells 208). In some embodiments, the top DBR 204 may be formed using 30 AlAs/Al_{0.20}Ga_{0.80}As mirror pairs, the bottom DBR 206 may be formed using 36 AlAs/Al_{0.20}Ga_{0.80}As mirror pairs, and the microcavity 210 portion itself (e.g., a half wavelength cavity) may be formed by 4×7 nm GaAs quantum wells and 4 nm Al_{0.40}Ga_{0.60}As barriers. It should, however, be understood that these are just example materials, and an example structural design, and other materials and sample design specifications should also be considered within the scope of this disclosure. For example, instead of GaAs, materials such as InP and ZnO, and related alloys can be used for constructing the heterostructures described herein. Further, different numbers of DBR pairs and numbers of quantum wells, and also distinct, but functionally similar designs may be used.

It is known in the art that fabricated confining potentials for polaritons may be achieved by employing a spatial modulation of either E_{P} (i.e., energy of the cavity photon mode) or E_{X} (i.e., energy of the cavity exciton mode). These techniques may depend on the initial value of Δ, i.e., the difference between E_{P} and E_{X}, where photonic techniques are more effective for Δ<0 (red detuning) corresponding to large initial photon fraction, and excitonic techniques are likewise most effective for Δ>0 (blue detuning), corresponding to a large initial exciton fraction.

Starting from the fabricated confining potentials, embodiments disclosed herein may simultaneously and strongly define landscapes for both photons 212 and excitons 202 with minimal sample degradation (i.e., maintaining a narrow linewidth). Independent control over photon 212 and exciton 202 energies permits not only tailoring of the energy landscape, but also the polariton lifetime and effective mass may be spatially structured, enabling generation of integrated non-Hermitian and topological photonic devices. As discussed throughout the disclosure, the use of high-energy ion implantation (e.g., proton implantation) may modulate the polariton energy and mass of both the exciton and photon components independently. The embodiments may provide for a creation of a deep, arbitrarily designed, and independently confining geometries for both photonic and excitonic polaritons.

Irradiation of high energy ions into a semiconductor material may generate lattice defects through multiple scattering events of energetic ions with the semiconductor lattice. Subsequent annealing of these defects can then promote interdiffusion/intermixing through diffusion of point defects across heterointerfaces. Embodiments disclosed herein use proton as the irradiation species, as protons are already an optically inactive interstitial atom incorporated during growth, and further as the lightest ions protons predominantly create point defects and dilute defect clusters. In contrast, heavier ions (e.g., As or Ga) can create defect clusters and also create extended defects (different from point defects), both of which cannot be easily removed by annealing. It should, however, be understood that the proton used for irradiation/implantation is just an example, any kind of implantation atomic species should be considered within the scope of this disclosure.

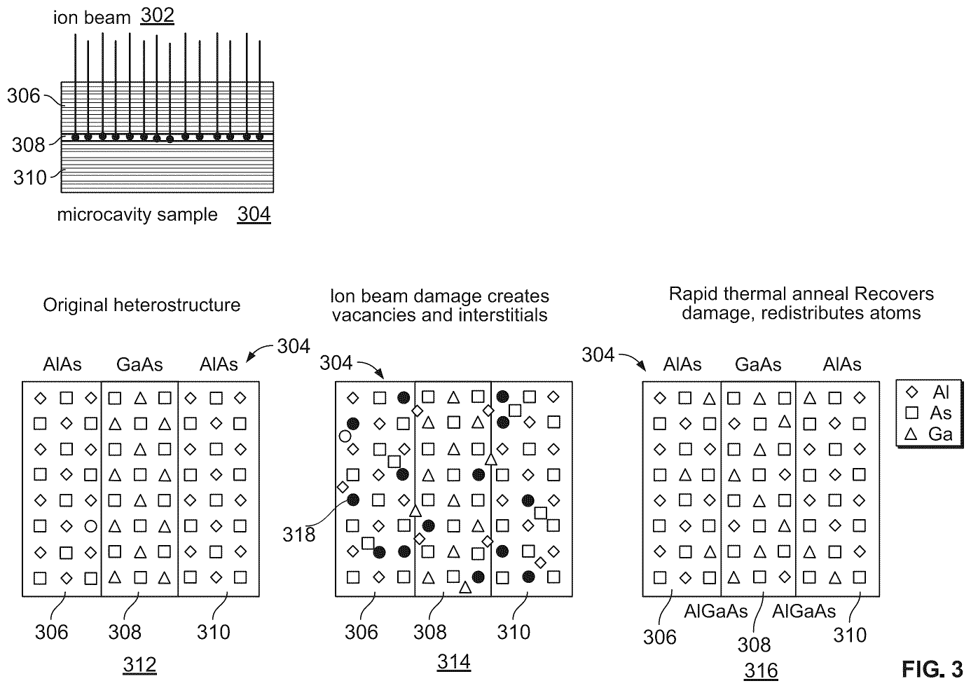

FIG. 3 shows an example implantation of an ion on a microcavity, according to example embodiments of this disclosure. As shown, an ion beam 302 (e.g., protons formed by Hydrogen ions) may be irradiated onto a microcavity sample 304 (similar to semiconductor microcavity 200, or a portion thereof, as shown in FIG. 2). As shown, the microcavity sample 304 includes a top DBR layer 306, bottom DBR layer 310, and quantum wells 308. The implantation changes the original heterostructure 312 of the microcavity sample into an intermediate structure 314 with vacancies 318.

The protons in the ion beam 302 may accelerated up to keV or MeV energies—or generally, any desired energy level—and impacted onto the sample surface (e.g., surface of the top DBR layer 306 of the microcavity sample 304). In some embodiments, the impact may be at an angle off of the normal incidence angle to restrict ion channeling dynamics. For example, the protons may be 2 degrees (just an example, not to be considered limiting) off the normal incidence angle. The impacted protons penetrate to a depth, where the amount of penetration is typically determined by one or more of the composition of the microcavity sample 304, structure of the microcavity sample 304, ion species of the ion beam 302, and ion energy of the ion beam 302. The ion energy Eᵢₒₙ can be precisely tuned via the acceleration voltage to create a depth-dependent distribution of vacancies 318 (e.g., created by atoms knocked off the lattice structure by the impact of the ion beam 302). Generally, any kind of vacancy and atomic density distributions thereof can be created at any position in the structure, with the example specifically referencing vacancies in the top DBR layer 306 and/or the quantum wells 308 layer using the implantation.

The intermediate structure 314 may then be annealed to redistribute the atoms and remove the vacancies 318 to realize the finalized, tuned microcavity 316. Generally, for low ion doses, the fluence of ions (ions/cm²), a subsequent rapid thermal anneal (RTA) may heal the defects in the intermediate structure 314 and restore crystallinity. For example, the original heterostructure 312 is undisturbed prior to irradiation. Once the ion beam 302 is used, a damage is caused that creates vacancies 318, as shown in the intermediate structure 314. The healing of the defects causes a restoration of crystallinity, e.g., as shown in the finalized, tuned microcavity 316. For defects in the proximity of a heterointerface and above an activation density, an interdiffusion of the two materials occurs (i.e., exchange of Ga and Al in some examples), inducing a smoothed potential gradient (from an initially atomically abrupt profile) of the heterostructure.

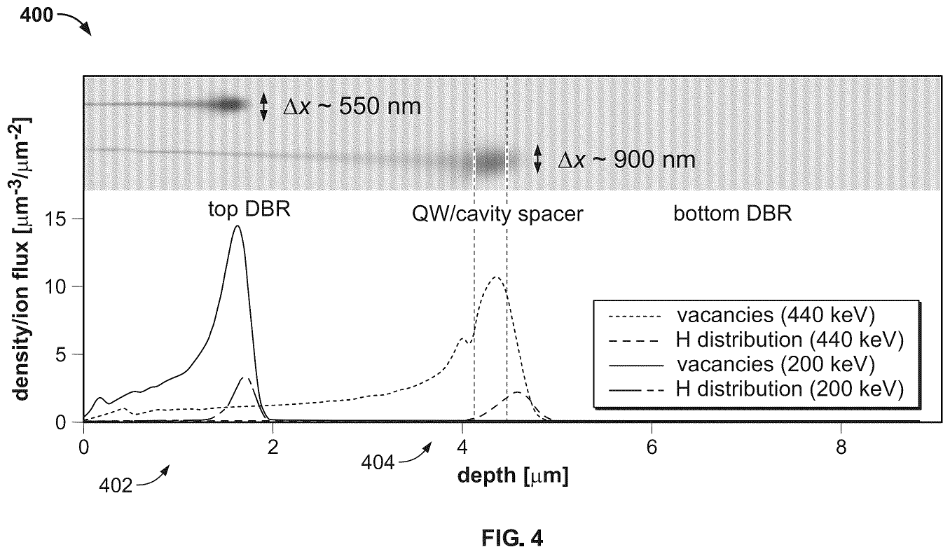

FIG. 4 shows an example Monte-Carlo ion scattering numerical simulations 400 of ions and vacancy density distributions after an ion implantation, according to example embodiments of this disclosure. The example numerical simulations 400 are on a microcavity sample that may include thirty six mirrors at the top layer and thirty two mirrors at the bottom layer. This configuration of mirrors may form a λ/2 cavity with 3 sets of 4×12 nm wide GaAs/AlAs quantum wells. A first set of quantum wells may be placed at anti-node of the cavity, a second set of quantum wells may be placed on the top mirrors, and a third set of quantum wells may be placed on the bottom mirrors. The Rabi splitting between the quantum wells may be 2-ℏΩ≈9.4 meV. It should be understood that the specific energies are just simulation examples and should not be misconstrued as a sole use case. Any kind of energy for the ion implantation should be considered within the scope of this disclosure. For instance, the different implant energies described below are just for illustrative purposes only.

The simulations may be for ion energy (Eᵢₒₙ)=200 keV (generating graph 402) and Eᵢₒₙ=440 keV (generating graph 404). These specific energies may be chosen such that the vacancy distribution is peaked either in the top DBR (e.g., top DBR layer 306 shown in FIG. 3) or cavity quantum wells (e.g., quantum wells 308, also shown in FIG. 3). A peak vacancy distribution in the top DBR (e.g., as shown by the graph 402) may be configured to modify the photon component and a peak vacancy distribution in the cavity quantum wells (e.g., as shown by the graph 404) may be configured to modify the exciton component.

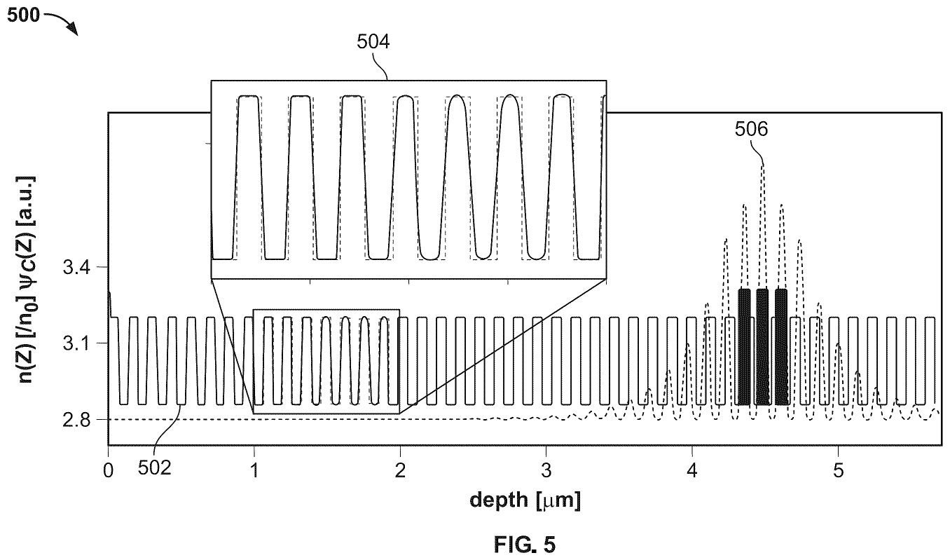

FIG. 5 shows a graph 500 illustrating vacancies distribution in the top DBR of the microcavity, according to example embodiments of this disclosure. The graph 500 particularly illustrates that for vacancies distributed in the top DBR, the refractive index profile n(z) after annealing becomes locally smoothed proportional to the vacancy distribution before annealing n_{vac}(z). The modified n(z) is calculated by solving the Fick diffusion equation ∂n(z)/∂t=∇ (D(z)∇n(z)), where D(z)=Dn_{vac}(z) is the diffusion coefficient, which gains a depth dependency through n_{vac}(z). The graph 500 shows Fick diffusion of the example heterostructure interface smoothing 502 for a 200 keV proton implant and a magnified section 504 to show the smoothing in more detail. The graph 500 additionally shows the corresponding transfer-matrix simulated cavity photon mode 506. In this microcavity sample, the asymmetry induced by the modulation of the top DBR shifts the photon to higher energy (E_{C}→E_{C}⁰+ΔE_{C}) leading to a large change in the lower polariton energy, E_{LP}, while the high cavity Q-factor is maintained at the vacancy densities.

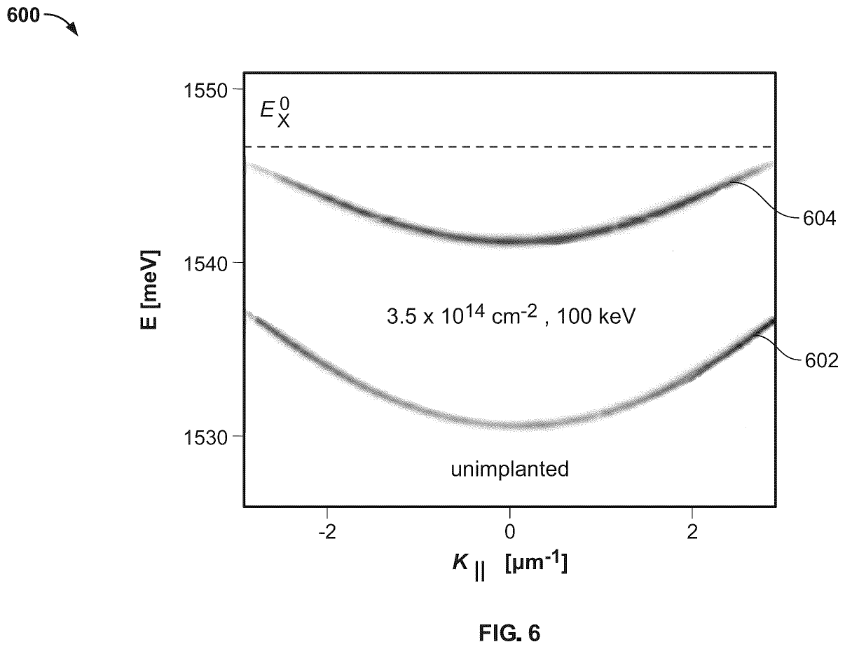

FIG. 6 shows an example graph 600 illustrating experimental photoluminescence (PL) measurements, according to example embodiments of this disclosure. The graph 500 particularly shows measurements of E_{LP}(k_{∥}), where k_{∥} is the in-plane momentum. After a 100 keV proton implant (with an example dose of 3.5×10¹⁴, cm⁻²), it can be shown that an initially photonic polariton mode 602 (e.g., Δ˜−12 meV) may be shifted to a higher energy 604 (e.g., ΔE_{LP}=10.6 meV) and becomes perceptibly heavier (5×10⁻⁵ mₑ⁰→7.2×10⁻⁵ mₑ⁰), due to increased exciton fraction.

For an example proton energy of Eᵢₒₙ=440 keV, the vacancy distribution may overlap all 12 quantum wells at a depth of ˜4.24 μm. After annealing, the atomically abrupt profile of the quantum wells may soften towards an error function-like potential.

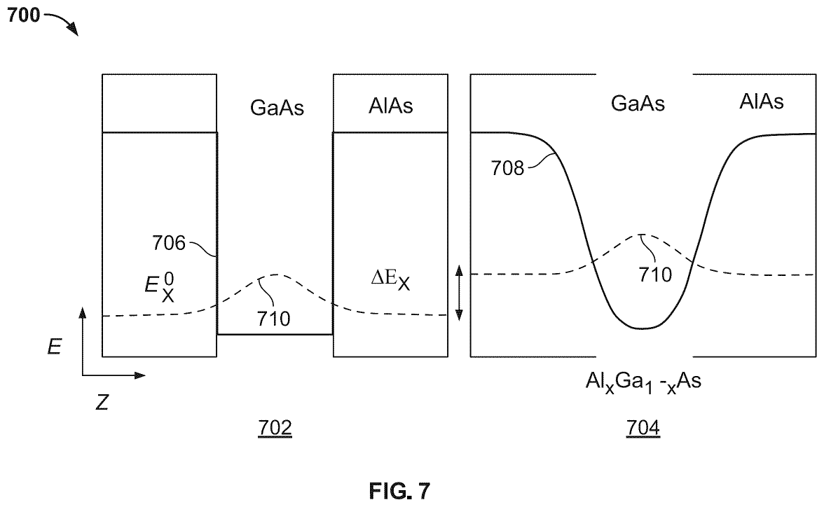

FIG. 7 shows example charts illustrating softening of the atomically abrupt profile of quantum wells, according to example embodiments of this disclosure. Particularly, the first chart 702 illustrates an abrupt profile of the quantum well 706 and an example second chart 704 illustrates a softened profile 708 of the quantum well. In addition, the exciton 710 has also been shifted, due to the annealing, to a higher energy state (E_{X}→E_{X}⁰+ΔE_{X}).

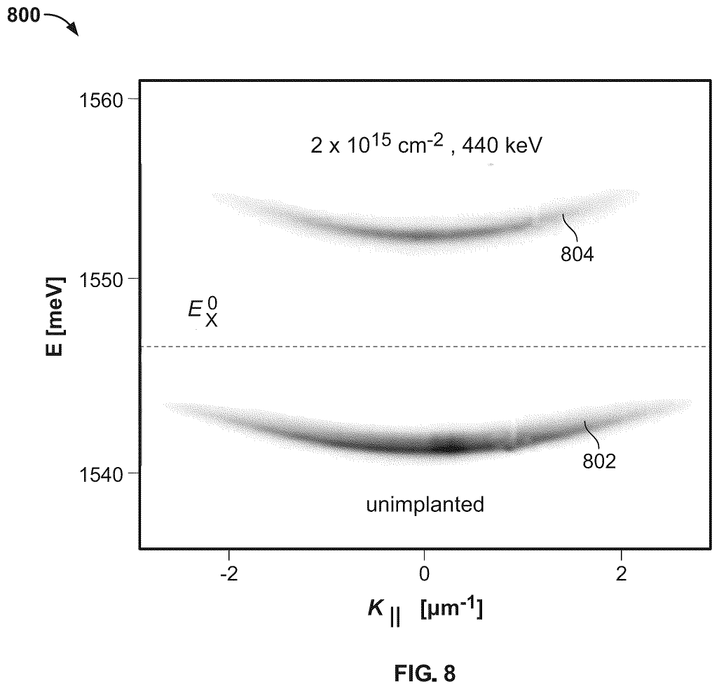

FIG. 8 shows an example chart 800 illustrating an experimental PL measurement, according to example embodiments of this disclosure. Particularly, the chart 800 shows E_{LP}(k_{∥}) before and after a 440 keV proton implant with a dose of 20×1014 cm⁻². The chart 800 particularly illustrates that an initially excitonic polariton mode (Δ˜7 meV) is shifted from a lower energy 802 to a higher energy 804 of ΔE_{LP}=11.53 meV. The excitonic polaritonic mode, however, may become lighter in mass (2.3×10⁻⁴ mₑ⁰→1.0×10⁻⁴ mₑ⁰) though still heavier than the bare cavity photon (m_{P}≈4×10⁻⁵ mₑ⁰). The new LP mode may be shifted in energy far above E_{X}⁰ unambiguously identifying a shift of the exciton energy as the mechanism for changing E_{LP}.

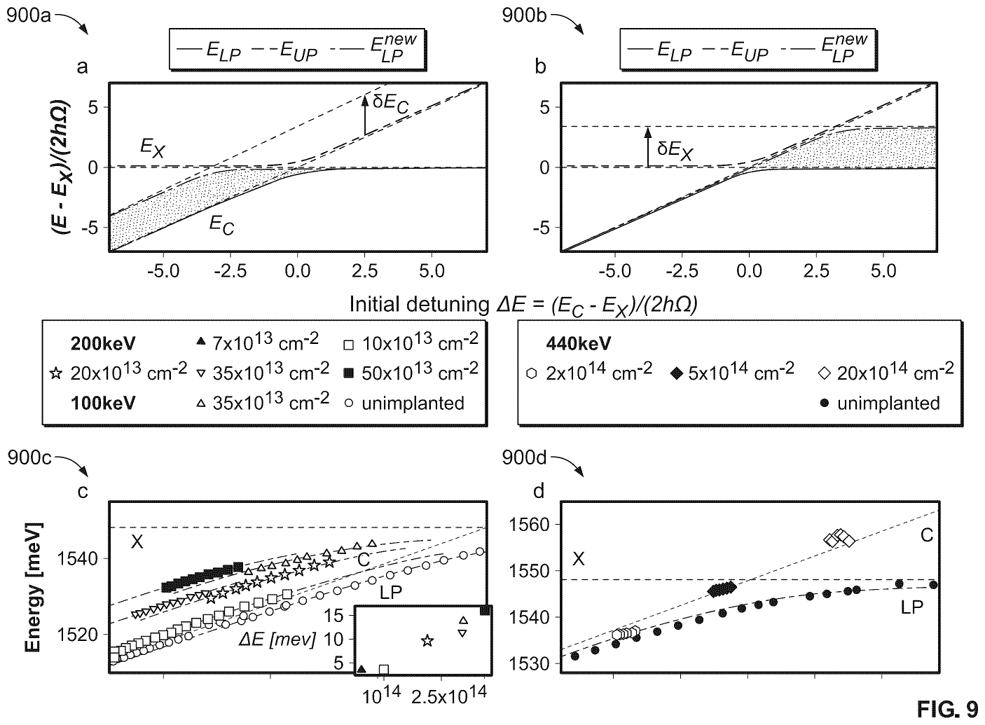

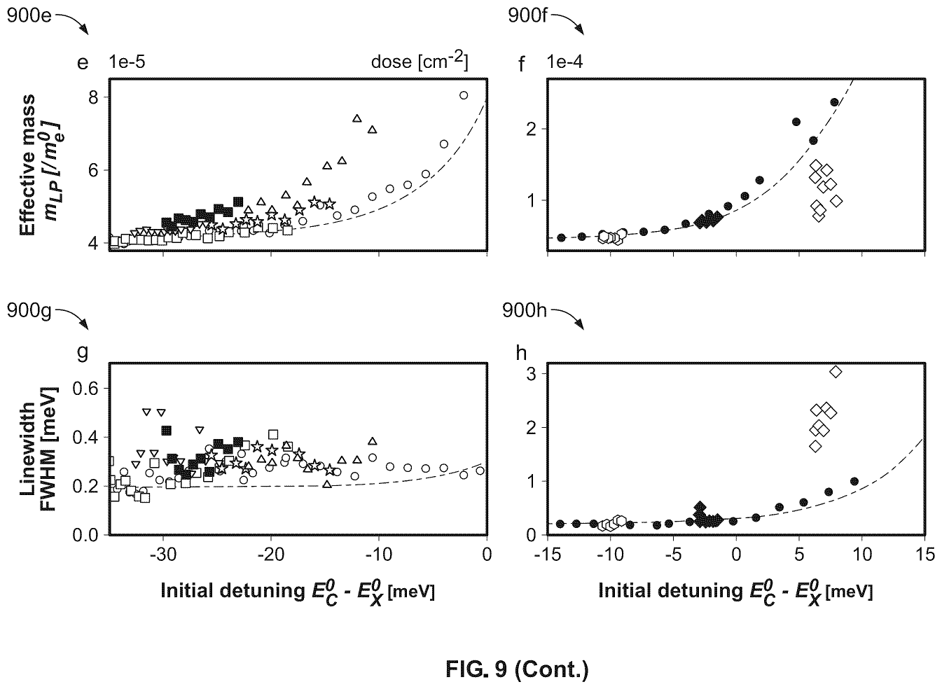

FIG. 9 shows accumulated results of proton implants at a range of doses at the example implant energies, according to example embodiments of this disclosure. The implant energies may be relevant to both exciton (Eᵢₒₙ=440 keV) and photon (Eᵢₒₙ={100, 200} keV). The samples contain a range of initial exciton-photon detuning Δ⁰E_{C}⁰−E_{X}⁰, and corresponding polariton energy E_{LP}, mass m_{LP} and lifetime γ_{LP}. Δ⁰ may be varied experimentally by incorporating a spatial dependency to the deposition rate during sample growth, inducing an approximately linear gradient of E_{C}⁰ with sample position, while leaving E_{X}⁰ relatively unchanged. Δ⁰ may also be altered in the growth stage by other methods with equivalent results. The proton beam may be scanned across the samples to ensure dose homogeneity. After implantation, the samples may be thermally annealed at 900° C. for 30 s (these values are just examples for experimentation purposes), recovering implant damage and promoting interdiffusion.

At each implant dose the LP energy E_{LP}(k_{∥}≈0), polariton mass m_{LP}, and PL linewidth at k_{∥}≈0 may be characterized. Samples may be pumped off-resonantly with a continuous-wave (CW), single-mode laser of ˜20 μm diameter tuned to the first Bragg minima of the cavity at an optical excitation power of ˜300 μW, which may be far below the condensation threshold (i.e., Pi≤0.2 Pₜₕ) ensuring polariton non-linearity does not contribute significantly to the energy shift. The data is plotted against the initial detuning (i.e. before implant) together with that of an unimplanted sample of similar detuning. For example, example chart 900a illustrates that shifting the energy of the cavity photon mode E_{C}→E_{C}⁰+δE_{C} affects the LP mode appreciably only for negative detuning Δ⁰≤0. Correspondingly, example chart 900b illustrates that a shift to the exciton energy E_{X}→E_{X}⁰+δE_{X} may shift the LP mode strongly only for initially positive detuning Δ0≥0. The regions |Δ⁰|≤2 ℏΩ respond to changes to both E_{C} and E_{X}, albeit with smaller shifts, as E_{LP} saturates to either E_{X} and E_{C}, respectively.

Considering first the cavity photon modification (i.e., Eᵢₒₙ={100, 200} keV), for all proton doses, E_{LP} may be shifted positively, as illustrated by the example chart 900c, up to a maximum ΔE_{LP}≈16.5 meV. Doses are sufficiently low such that the energy shift logarithmically increases with dose (vacancy concentration) and does not saturate, as illustrated in the insert for chart 900c. m_{LP} may increase monotonically with proton dose, as illustrated by the example chart 900e, and more strongly so for less negative initial detuning, corresponding to an increase of exciton fraction consistent with a shift of E_{C} increasing Δ, as illustrated by example chart 900f. The increased effective mass under all implant conditions demonstrates strong exciton-photon coupling is maintained. A larger increase to both E_{LP} and m_{LP} is observed for Eᵢₒₙ=100 keV relative to the equivalent dose at Eᵢₒₙ=200 keV. Despite the lower energy implant creating vacancies farther away from the cavity, n_{vac}(z) has a narrower spread in z and a larger peak density, thus resulting in larger energy shifts. Transfer matrix simulations show that the precise shift to the LP mode induced by an implant into the top DBR may have a complex dependency on implant energy, implant dose, and the precise structure of the cavity. Notably, the energy shift may be in a positive or negative direction.

Proton implants at a larger proton energy (Eᵢₒₙ=440 keV) distribute vacancies in the cavity quantum wells and are expected to increase E_{X} and again, a monotonic increase in E_{LP} is observed with proton dose, as illustrated by example chart 900d. It has been found that proton-implantation induced interdiffusion in bare quantum wells have similar results in increased exciton energy with increasing implant dose. In a polariton microcavity, however, the cavity mode may convolute direct interpretation of the energy shift. At the larger two proton doses, E_{LP} is observed to saturate at E_{C} as anticipated for sufficiently large dose. Further, at the highest dose (20×10¹⁴ cm⁻²), E_{LP} moves slightly beyond E_{C}. This is due to a shift also of E_{C} to higher energies resulting from the concomitant introduction of vacancies into the top DBR by the tail of the 440 keV proton implant (e.g., as described in reference to FIG. 4 above). According to example simulations, the peak proton dose in the top DBR from a Eᵢₒₙ=440 keV implant is ˜0.15(20×10¹⁴)=3×10¹⁴ cm⁻², sufficient to introduce a few meV shift also to E_{C}. Although the initial detuning was not sufficiently large to observe a shift in imp for the two smaller doses, the largest dose shows a clear reduction of m_{LP} further demonstrating that the shift to E_{LP} is dominated by a shift of E_{X}. The mass is still significantly above the photon mass m_{C}, and thus a strong coupling is maintained.

Next, the k_{∥}≈0 PL linewidth (FWHM) is characterized for implants into the top DBR, as illustrated by example chart 900g, and the cavity, as illustrated by example chart 900h, to reveal any residual device degradation. For top DBR implants, negligible shifts of the PL linewidth relative to unimplanted samples are observed, as also illustrated by example chart 900g, suggesting the cavity Q-factor is nominally unchanged. The point-to-point variation due to disorder is larger than any implant-induced damage. For implants into the cavity quantum wells, as illustrated by example chart 900h, the linewidth is only broadened appreciably for the largest dose. It is understood that this condition may also be improved by further parameter optimization. Linewidth degradation in the exciton shifted samples may potentially result from both cavity degradation (the top DBR is implanted through) in addition to residual disorder-induced inhomogeneous broadening of the quantum well interfaces. A broadened PL linewidth may also result if each of the 12 quantum wells are not shifted equally due to implant-induced vacancy distribution varying across the quantum wells. Comparing with previous quantum well interdiffusion measurements would indicate the latter is dominant, and the calculations based on the embodiments disclosed herein (e.g., as described in reference to FIG. 4 above) estimate a 2-4 meV variation across the 12 quantum wells, consistent with this interpretation. Customizing a structure with smaller compositional abruptness of the quantum wells and fewer total quantum wells may improve the efficacy of the implantation technique for exciton shifts. Further, multiple (i.e., 2 or 3) implants of fractional doses at slightly different energies may flatten the vacancy distribution across the entire cavity region. Aside from effects resulting from sample degradation, broadening of the LP mode will also occur when the exciton fraction is increased and conversely, will be reduced when the photon fraction is increased.

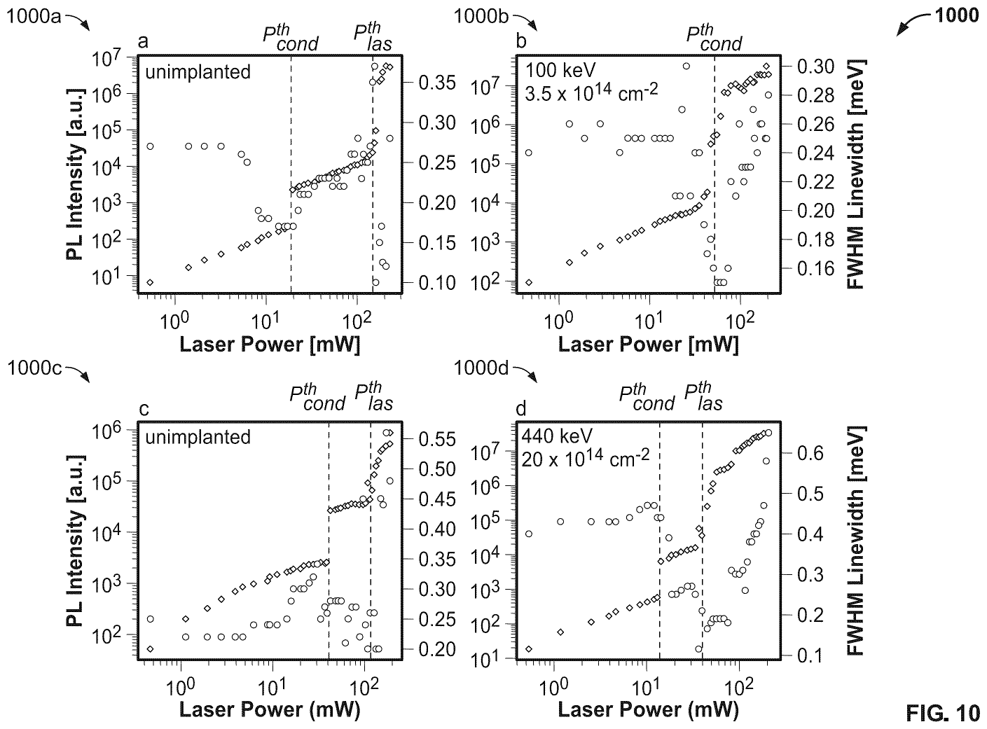

FIG. 10 shows example charts 1000a-1000d illustrating polariton condensation and photon lasing transitions, according to example embodiments of this disclosure. Particularly, example chart 1000a illustrates condensation state, expressed as integrated PL intensity I_{PL}(k_{∥}≈0) and linewidth γ_{PL}(k_{∥}≈0), before a 100 keV implant and example chart 1000b illustrates the condensation state after the 100 keV implant. As another example, example chart 1000c illustrates condensation state, also expressed as integrated PL intensity I_{PL}(k_{∥}≈0) and linewidth γ_{PL}(k_{∥}≈0), before a 440 keV implant and example chart 1000d illustrates the condensation state after the 440 keV implant. The sample may be pumped with a CW, off-resonant laser of 70 μm diameter, ensuring condensation spontaneously, ensuring that the condensation occurs at k_{∥}≈0. As described above, these specific values (including the specific implant energy values) are just for illustrative purposes only, and should not be considered limiting.

For the photon-shifting implant conditions, shown in example charts 1000a, 1000b, two thresholds P_{cond}^{th}=18.7 mW and Pₗₐₛ^{th}=149.0 mW may be observed before implantation, corresponding to condensation and lasing transitions respectively, in order of increasing power. At each transition, discontinuities in both I_{PL} and γ_{PL} may be observed. After implantation at 100 keV and 3.5×10¹⁴ cm⁻², the first threshold occurs at higher power P_{cond}^{th}=52.0 mW, while the second threshold is absent. The qualitative similarity of the condensation characteristics suggest the lasing transition occurs at a larger power than was experimentally available. The kinetics of polariton condensation and the associated threshold may be determined by numerous factors, including relaxation rates and thermalization dynamics, which in turn depend on specifics of the sample and the optical pump, and the exciton-photon detuning. The dominant contribution to the P_{cond}^{th} increase may result from the increased LP lifetime arising from the blue shift of detuning from Δ⁰=−12 meV→Δ≈−1 meV.

For the exciton-shifting implant conditions, shown in example charts 1000c, 1000d, two thresholds are again observed before implantation at P_{cond}^{th}=40.6 mW and Pₗₐₛ^{th}=117.0 mW. After implantation under conditions of 440 keV of 20×10¹⁴ cm⁻², two thresholds may still be observed, at P_{cond}^{th}=13.7 mW and Pₗₐₛ^{th}=39.8 mW, both at lower power. The reduced lifetime and faster scattering dynamics of the red-shifted polariton detuning from Δ⁰=+7 meV→Δ≈+2 meV, may be attributed.

Therefore, in these embodiments, proton implantation into planar microcavities controllably modifies either the photon or exciton energy while narrow-linewidth (at sufficiently low proton dose) polariton modes and condensation may be maintained. Further, photon lasing transitions are also evidenced with performance metrics similar to those of high quality lasing devices, which are unmodified by implantation. The embodiments can be further extended to a spatially structured proton implantation (e.g., through a physical mask). Numerical simulations (as shown in FIG. 4) allow an estimation of the minimum lateral scale of the proton implant-induced modifications. This lateral spread of vacancies at the peak depth may increase with depth (e.g., at higher Eᵢₒₙ), however, even for the extreme case of implants targeting the cavity region of a thick, high-Q GaAs microcavity, spatial structures of Δx≤1 μm (FWHM) may be possible. As potential depths may be in excess of 10 meV, ideal parameters for tight-binding polariton lattices may be achievable, applicable equally to both photons and excitons.

While conventional techniques have considered fabricated potential landscapes using the photon component, confinement through the exciton fraction is also desired. For example, in a GaAs-based microcavity, typical photon and exciton masses may be m_{C}˜3×10⁻⁵ m₀ and m_{X}˜0.2 m₀, respectively, where m₀ is the free electron mass, thus ˜10⁴ range of mass tuning of the lower polariton state may be available. However, the highly non-linear relationship between effective mass and exciton |X|² or photon |C|² fractions,

$${m}_{LP}^{- 1} = \frac{{\vert x \vert}^{2}}{{m}_{X}} + {\vert C \vert}^{2} / {m}_{C} ,$$

where X and C are the exciton and photon Hopfield coefficients respectively, may require that very high exciton fraction (e.g., |X|²≥0.9) polaritons are necessary to see such large variations in the effective mass. The detuning also controls the polariton non-linearity, with higher exciton-fraction polaritons being more strongly interacting. The use of proton implantation to produce lattices of tightly-confined, heavy polaritons may thus enable the observation of phase transitions such as a superfluid-Mott insulator transition, and further, potential landscapes incorporating spatial modulation of effective mass are also possible.

Being able to independently tune both the exciton and photon energies may enable new techniques to explore integrated, structured non-Hermitian matter, e.g., landscapes that are complex valued, which are particularly relevant for parity time (PT)-symmetry. By employing a dual-energy structured proton implant, the energy landscape may become V(r)=E_{LP}(r)−ihγ_{LP}(r), as polariton decay rate γ_{LP}(Δ(r)) may vary with detuning Δ(r)=E_{C}(r)−E_{X}(r), constituting an imaginary potential for on-chip structured, non-Hermitian polariton landscapes.

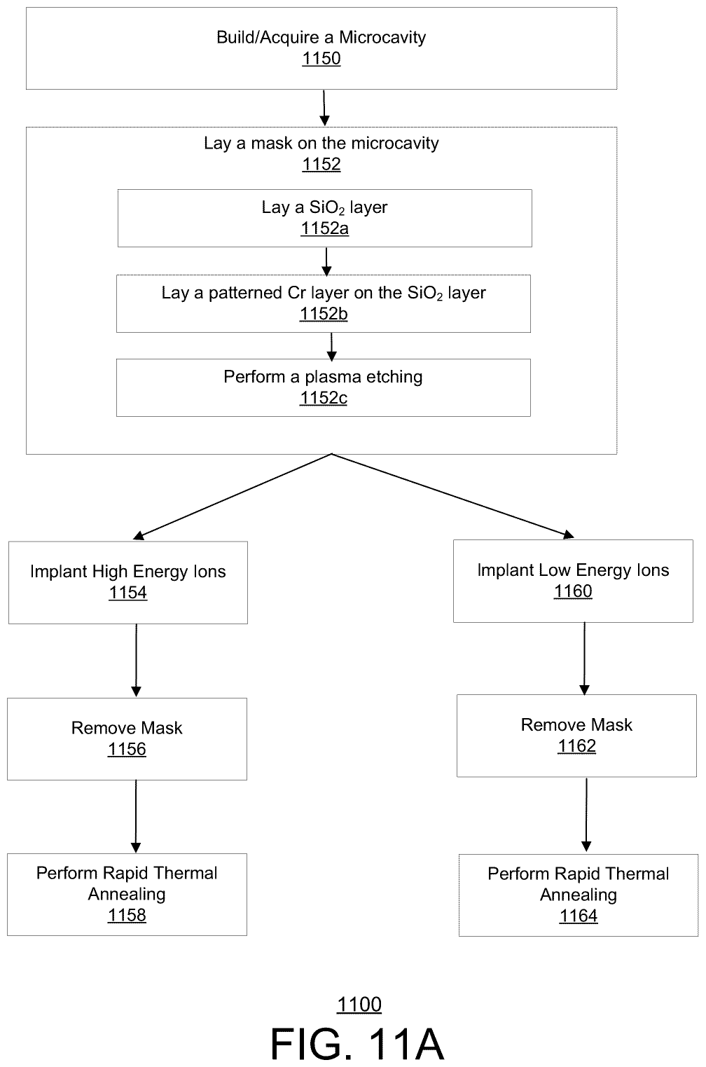

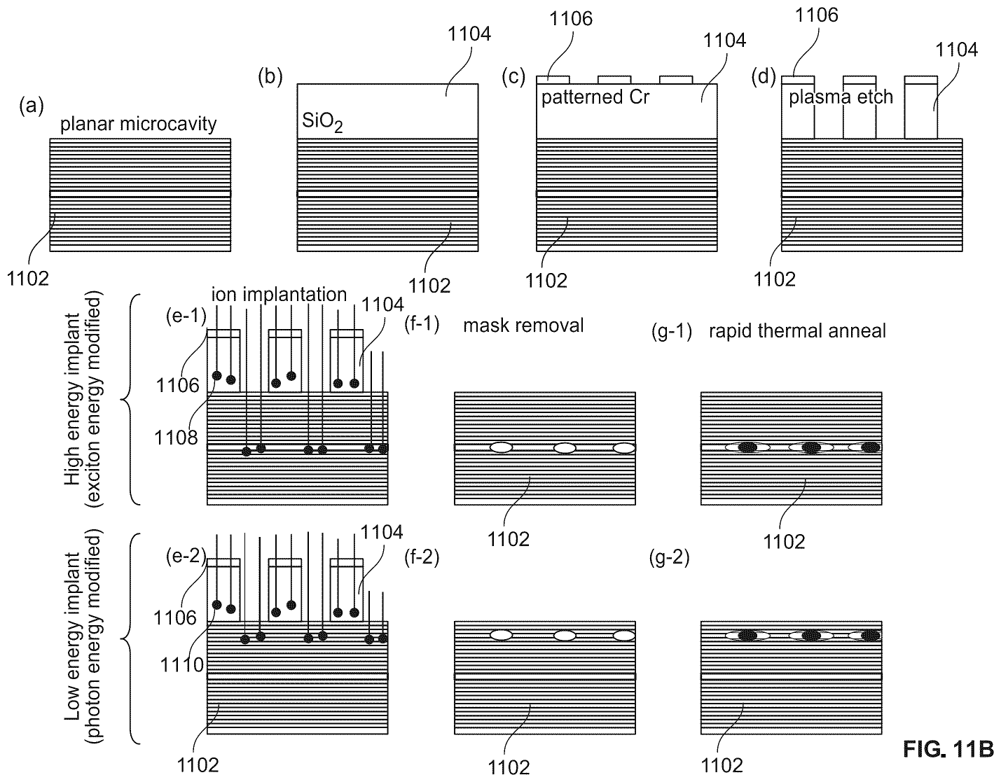

FIG. 11A shows an example method 1100 of fabricating of a structured landscape, according to example embodiments of this disclosure. FIG. 11B shows the different structures generated by the steps of the method 1100, according to example embodiments of this disclosure.

The method 1100 begins at step 1150 where a planar microcavity 1102 may be built/acquired.

At step 1152, a mask may be laid upon the top DBR of the planar microcavity 1102. Step 1152 may include three sub-steps 1152a-1152c. At sub-step 1152a, a SiO₂ layer 1104 (or a layer with similar physical properties) may be laid. In some embodiments, a thin SiNₓ film (or a thin film with similar physical and structural properties) may optionally be incorporated between the planar microcavity 1102 and the SiO₂ layer 1104 to protect the planar microcavity 1102 during the subsequent steps. At sub-step 1152b, a patterned Cr layer 1106 may be laid on the SiO₂ layer 1104. At sub-step 1152c, a plasma etching may be performed to remove the SiO₂ at locations not covered by the Cr layer 1106.

After the masking step 1152, the method 1100 may be bifurcated—for example, steps 1154-1158 may use a high energy implant to modify exciton energy and steps 1160-1164 may use a low energy implant to modify photon energy.

For the high energy implant, an ion implantation with high energy ions 1108 may be performed at step 1154 through the mask formed by the SiO₂ 1104 and the patterned Cr layer 1106. At step 1156, the mask may be removed. At step 1158, a rapid thermal annealing may be performed to generate the microcavity 1102 is a modified exciton energy.

For the low energy implant, an ion implantation with low energy ions 1110 may be performed at step 1160 through the mask formed by the SiO₂ 1104 and the patterned Cr layer 1106. At step 1162, the mask may be removed. At step 1164, a rapid thermal annealing is performed to generate the microcavity 1102 is a modified photon energy.

It should however be understood that the modification of the exciton energy and the modification of the photon energy is not necessarily an either or proposition: both the exciton and photon energy can be tuned together through the implantation. Additionally, the mask be used to tune the microcavity 1102 with distinct spatial configurations using the embodiments disclosed herein.

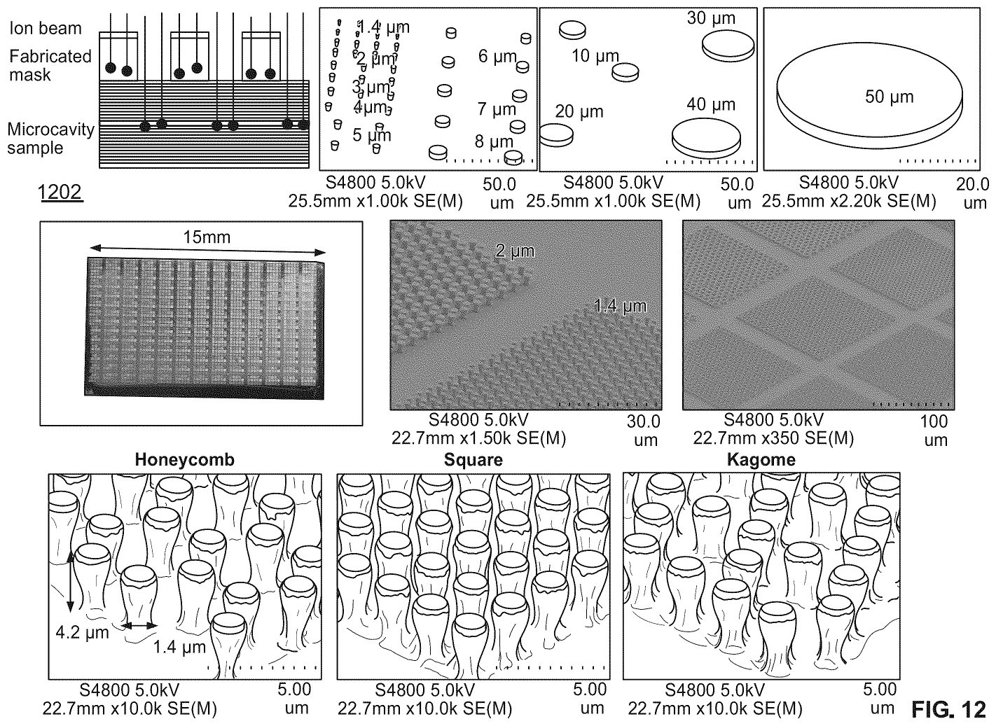

FIG. 12 shows several examples of microcavity shapes and sizes, according to example embodiments of this disclosure. As shown, an ion implantation 1202 may be performed on a microcavity structure using a mask to generate different landscapes. The microcavity structure can be any size and shapes, e.g., as shown circular shapes ranging from 1.4 μm to 50 μm. Further, each cavity in the microcavity structure can be shaped differently, such as a honeycomb, square, or Kagome.

Because each microcavity can be tuned, by tuning its excitonic and/or photonic energy, a plurality of microcavities can be formed within a single chip, wherein each microcavity has its own resonant frequency. This setup—with multiple uniquely tuned microcavities on a single chip—can be used for various applications such as wavelength division multiplexing.

Therefore, the embodiments disclosed herein demonstrate techniques for inducing large post-growth shifts 10's of meV) to microcavity exciton-polaritons, the first capability of independently modifying the exciton and/or photon energies. By independently adjusting both, exciton-polaritons may be created with almost arbitrary absolute energy and exciton-photon detuning, with the latter giving control over the effective mass, decay rate and interaction strength. Sample quality is minimally impacted and both strong-coupling and polariton condensation are maintained. If the technique is extended to structured landscapes, sub-1 μm confinement is possible, enabling lattices structures incorporating modulation of not only energy but also mass and decay rate, and opening new opportunities to explore topological and non-Hermitian states in a strongly non-linear, coherent photonic platform.

Not only the embodiments disclosed herein can generate a chip that emits different coherent wavelengths in the vertical direction. Embodiments disclosed herein can generate chips through tuned implantation—that generate different wavelengths in the horizontal direction as well. The chip can be a coherent photonic circuit for exciton-polariton based optical computing circuit devices, which may be based on classical or quantum functionality.

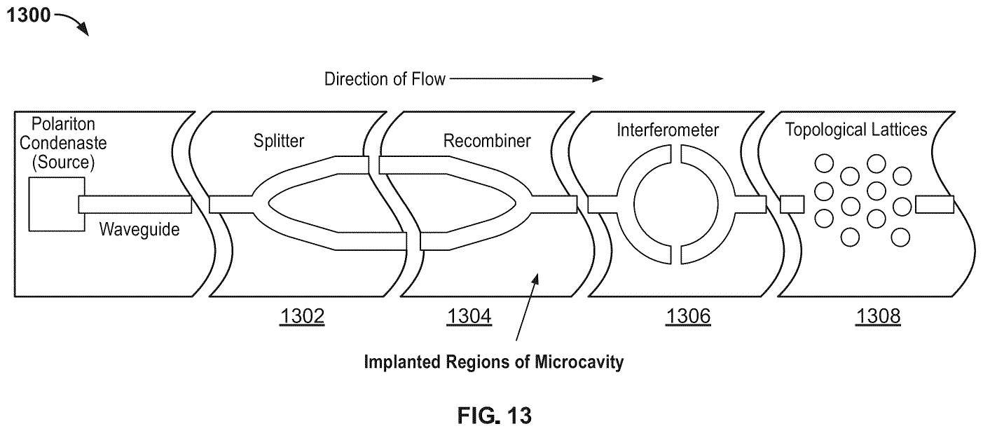

FIG. 13 shows an example photonic circuit 1300, according to example embodiments of this disclosure. The photonic circuit 1300 may be a coherent photonic circuit formed by different types of photonic elements, including waveguides, beam splitters (fan-in and fan-out operations), interferometers, Josephson junctions to list a few. As shown, the photonic circuit 1300 may include tuned channels formed by spatially varying the resonating frequency of a semiconductor microcavities: splitter 1302, recombiner 1304, interferometer 1306, and topological lattices 1308. The transmission of the optical signal through the photonic circuit 1300 can be from the left to right. The transmission of the optical signal may be in the form of polaritons; and at each spatial location in the semiconductor microcavity (e.g., splitter 1302, recombiner 1304, interferometer 1306, topological lattices 1308), the optical signal may be changed—based on the level of implantation to the corresponding cavity—to support the desired computation/signal processing. The photonic circuit 1300 can be part of photonic devices that support superfluid transport, provide high-speed processing (e.g., ps or fs switching time), show very strong non-linearity, and control gain and loss for circuits exhibiting non-Hermitian functionality.

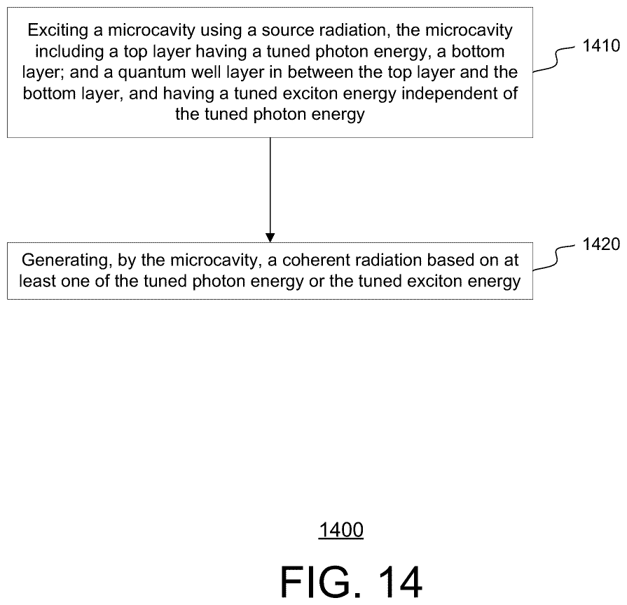

FIG. 14 is a flowchart of an example method 1400 for generating a coherent radiation, according to example embodiments of this disclosure.

The method 1400 may begin at step 1410 where a microcavity may be excited using a source radiation. The microcavity may include a top layer having a tuned photon energy, a bottom layer, and a quantum well layer in between the top layer and the bottom layer, and having a tuned exciton energy independent of the tuned photon energy.

At step 1420, the microcavity may generate a coherent radiation based on at least one of the tuned photon energy or the tuned exciton energy.

In some embodiments, a microcavity may include a top layer having a tuned photon energy; a bottom layer; and a quantum well layer in between the top layer and the bottom layer, and having a tuned exciton energy independent of the tuned photon energy.

In the microcavity, the top layer may include structural changes induced by implanted hydrogen ions that tune the photon energy independent of the tuned exciton energy. In the microcavity, the quantum well layer may include structural changes induced by implanted hydrogen ions that tune the exciton energy independent of the tuned photon energy. The microcavity may be configured to have a resonant frequency based on at least one of the tuned photon energy or the tuned exciton energy. The microcavity may be configured to generate a coherent radiation at a resonant frequency based on at least one of the tuned photon energy or the tuned exciton energy. In the microcavity, each of the top layer and the bottom layer may include Aluminum Arsenide (AlAs) and Aluminum Gallium Arsenide (AlGaAs). Other materials which support ion implantation induced interdiffusion, such as ZnO or InP and related allows may also be used. In the microcavity, each of the top layer and the bottom layer may be configured as a Distributed Bragg Reflector (DBR). The coherent radiation at the resonant frequency can be based on the tuned photon energy or the tuned exciton energy, and may arise from photon lasing based coherent radiation emission or polariton condensation based coherent radiation emission.

In some embodiments, an optical chip may include a plurality of microcavities, each microcavity configured for a corresponding resonant frequency, each microcavity includes: a top layer having a tuned photon energy; a bottom layer; and a quantum well layer in between the top layer and the bottom layer, and having a tuned exciton energy independent of the tuned photon energy, wherein the corresponding resonant frequency is based on at least one of the tuned photon energy or the tuned exciton energy.

In a microcavity of the optical chip, the top layer may include implanted hydrogen ions that tune the photon energy independent of the tuned exciton energy. In a microcavity of the optical chip, the quantum well layer includes structural changes induced by implanted hydrogen ions that tune the exciton energy independent of the tuned photon energy. In the optical chip, each microcavity may be configured to generate a coherent radiation at the corresponding resonant frequency. In a microcavity of the optical chip, each of the top layer and the bottom layer may include Aluminum Arsenide (AlAs) and Aluminum Gallium Arsenide (AlGaAs).). Other materials such as ZnO or InP may also be used as well. In microcavity of the optical chip, each of the top layer and the bottom layer may be configured as a Distributed Bragg Reflector (DBR). The coherent radiation at the resonant frequency can be based on the tuned photon energy is an optical lasing radiation. The coherent radiation at the resonant frequency can also be based on the tuned exciton energy is a condensate based radiation.

In some embodiments, a method of generating a coherent radiation may include: exciting a microcavity using a source radiation, wherein the microcavity includes: a top layer having a tuned photon energy; a bottom layer; and a quantum well layer in between the top layer and the bottom layer, and having a tuned exciton energy independent of the tuned photon energy; and generating, by the microcavity, a coherent radiation based on at least one of the tuned photon energy or the tuned exciton energy.

The generating of the coherent radiation may further include generating, by the microcavity, the coherent radiation at a resonant frequency based on at least one of the tuned photon energy or the tuned exciton energy. The coherent radiation at the resonant frequency can be based on the tuned photon energy or the tuned exciton energy, and may arise from photon lasing based coherent radiation emission or polariton condensation based coherent radiation emission.

In some embodiments, a method of generating a plurality of coherent radiations at a corresponding plurality of resonant frequencies may include exciting, using a source radiation, a plurality of microcavities on an optical chip, wherein each microcavity includes: a top layer having a tuned photon energy; a bottom layer; and a quantum well layer in between the top layer and the bottom layer, and having a tuned exciton energy independent of the tuned photon energy, generating, by the plurality of microcavities, a plurality of coherent radiations at a corresponding plurality of resonant frequencies based on corresponding at least one of the tuned photon energy or the tuned exciton energy.

The plurality of coherent radiations may be used for wavelength division multiplexing. The plurality of coherent radiation at the resonant frequency can be based on the tuned photon energy or the tuned exciton energy, and may arise from photon lasing based coherent radiation emission or polariton condensation based coherent radiation emission.

In some embodiments, a method of manufacturing a microcavity may include fabricating a microcavity having a top layer, a bottom layer, and a quantum well layer in between the top layer and the bottom layer; implanting hydrogen ions to the top layer and/or the quantum well layer to generate vacancies and interstitials in the heterostructure of the top layer and/or the quantum well layer; and performing a thermal annealing to redistribute atoms across the vacancies and the interstitials, such that the hydrogen ions implantation and the thermal annealing independently tune photon energy and exciton energy of the microcavity.

The independent tuning of the photon energy and the exciton energy may cause the microcavity have a resonant frequency. The plurality of coherent radiation at the resonant frequency can be based on the tuned photon energy or the tuned exciton energy, and may arise from photon lasing based coherent radiation emission or polariton condensation based coherent radiation emission.

In some embodiments, a method of manufacturing an optical chip may include laying a mask on a microcavity structure having a top layer, a bottom layer, and a quantum well layer in between the top layer and the bottom layer; implanting hydrogen ions to the top layer and/or the quantum well layer to generate vacancies and interstitials in the heterostructure of the top layer and/or the quantum well layer; and performing a thermal annealing to redistribute atoms across the vacancies and the interstitials, such that the masking, the hydrogen ions implantation, and the thermal annealing generate plurality of microcavities, each with independently tuned photon energy and exciton energy.

The independent tuning of the photon energy and the exciton energy may cause each of the plurality microcavities to have a corresponding resonant frequency different from other resonant frequencies. The plurality of coherent radiation at the resonant frequency can be based on the tuned photon energy or the tuned exciton energy, and may arise from photon lasing based coherent radiation emission or polariton condensation based coherent radiation emission. In some embodiments, a coherent photonic circuit device may include a plurality of microcavities, each microcavity configured for a corresponding resonant frequency, each microcavity includes: a top layer; a bottom layer; and a quantum well layer in between the top layer and the bottom layer, and having a tuned exciton or photon energy to transmit a condensate based radiation at the corresponding resonant frequency to a neighboring microcavity. The DBR layers or the quantum well layer may include structural modifications induced by implanted hydrogen ions that tune the exciton or photon energies respectively.

In some embodiments a method of using a coherent photonic circuit device may include exciting, a plurality of microcavities, each microcavity configured for a corresponding resonant frequency, wherein each microcavity includes: a top layer; a bottom layer; and a quantum well layer in between the top layer and the bottom layer, and having a tuned exciton or photon energy; transmitting, by a microcavity of the plurality of microcavities, a condensate based radiation at the corresponding resonant frequency to a neighboring microcavity. The DBR layers or the quantum well layer may include structural modifications induced by implanted hydrogen ions that tune the exciton or photon energies respectively.

In another embodiment, a method of manufacturing a coherent photonic circuit device may include laying a mask on a microcavity structure having a top layer, a bottom layer, and a quantum well layer in between the top layer and the bottom layer; implanting ions to the quantum well layer to generate vacancies and interstitials in the heterostructure of the quantum well layer; and performing a thermal annealing to redistribute atoms across the vacancies and the interstitials, such that the masking, the ions implantation, and the thermal annealing generate plurality of microcavities, each with a tuned exciton or photon energy. The tuning of the exciton or photon energy may cause each of the plurality microcavities to have a corresponding resonant frequency different from other resonant frequencies. The coherent radiation may be a condensate based or lasing based radiation.

Additional examples of the presently described method and device embodiments are suggested according to the structures and techniques described herein. Other non-limiting examples may be configured to operate separately or can be combined in any permutation or combination with any one or more of the other examples provided above or throughout the present disclosure.

It will be appreciated by those skilled in the art that the present disclosure can be embodied in other specific forms without departing from the spirit or essential characteristics thereof. The presently disclosed embodiments are therefore considered in all respects to be illustrative and not restricted. The scope of the disclosure is indicated by the appended claims rather than the foregoing description and all changes that come within the meaning and range and equivalence thereof are intended to be embraced therein.

It should be noted that the terms “including” and “comprising” should be interpreted as meaning “including, but not limited to”. If not already set forth explicitly in the claims, the term “a” should be interpreted as “at least one” and “the”, “said”, etc. should be interpreted as “the at least one”, “said at least one”, etc. Furthermore, it is the Applicant's intent that only claims that include the express language “means for” or “step for” be interpreted under 35 U.S.C. 112(f). Claims that do not expressly include the phrase “means for” or “step for” are not to be interpreted under 35 U.S.C. 112(f).

What is claimed is:

1. A microcavity comprising:
a top layer having a tuned photon energy;
a bottom layer; and
a quantum well layer in between the top layer and the bottom layer, and having a tuned exciton energy independent of the tuned photon energy.

2. The microcavity of claim 1, wherein the top layer comprises structural changes induced by implanted hydrogen ions that tune the photon energy independent of the tuned exciton energy.

3. The microcavity of claim 1, wherein the quantum well layer comprises structural changes induced by implanted hydrogen ions that tune the exciton energy independent of the tuned photon energy.

4. The microcavity of claim 1, wherein the microcavity is configured to have a resonant frequency based on at least one of the tuned photon energy or the tuned exciton energy.

5. The microcavity of claim 1, wherein the microcavity is configured to generate a coherent radiation at a resonant frequency based on at least one of the tuned photon energy or the tuned exciton energy.

6. The microcavity of claim 5, wherein the coherent radiation at the resonant frequency is based on optical lasing radiation.

7. The microcavity of claim 5, wherein the coherent radiation at the resonant frequency is based on condensate based radiation.

8. The microcavity of claim 7, wherein the condensate comprises a Bose-Einstein condensate.

9. An optical chip comprising:
a plurality of microcavities, each microcavity configured for a corresponding resonant frequency, each microcavity comprising:
a top layer having a tuned photon energy;
a bottom layer; and
a quantum well layer in between the top layer and the bottom layer, and having a tuned exciton energy independent of the tuned photon energy, wherein the corresponding resonant frequency is based on at least one of the tuned photon energy or the tuned exciton energy.

10. The optical chip of claim 9, wherein the top layer comprises structural changes induced by implanted hydrogen ions that tune the photon energy independent of the tuned exciton energy.

11. The optical chip of claim 9, wherein the quantum well layer comprises structural changes induced by implanted hydrogen ions that tune the exciton energy independent of the tuned photon energy.

12. The optical chip of claim 9, wherein each microcavity is configured to generate a coherent radiation at the corresponding resonant frequency.

13. The optical chip of claim 12, wherein the coherent radiation at the resonant frequency is based on optical lasing radiation.

14. The optical chip of claim 12, wherein the coherent radiation at the resonant frequency is a condensate based radiation.

15. The optical chip of claim 14, wherein the condensate comprises a Bose-Einstein condensate.

16. A method of generating a coherent radiation comprising:
exciting a microcavity using a source radiation, wherein the microcavity comprises:
a top layer having a tuned photon energy;
a bottom layer; and
a quantum well layer in between the top layer and the bottom layer, and having a tuned exciton energy independent of the tuned photon energy; and
generating, by the microcavity, a coherent radiation based on at least one of the tuned photon energy or the tuned exciton energy.

17. The method of claim 16, wherein generating the coherent radiation further comprises:
generating, by the microcavity, the coherent radiation at a resonant frequency based on at least one of the tuned photon energy or the tuned exciton energy.

18. The method of claim 17, wherein the coherent radiation at the resonant frequency is an optical lasing radiation.

19. The method of claim 17, wherein the coherent radiation at the resonant frequency is a condensate based radiation.

20. The method of claim 19, wherein the condensate comprises a Bose-Einstein condensate.
